(19) United States
(12) Patent Application Publication
(10) Pub. No.: US 2026/0164667 A1
(43) Pub. Date: Jun. 11, 2026

(54) SEMICONDUCTOR MEMORY DEVICE AND ELECTRONIC SYSTEM INCLUDING THE SAME

(71) Applicant: SAMSUNG ELECTRONICS CO., LTD., Suwon-si (KR)

(72) Inventors: Hanbit JUNG, Suwon-si (KR); Younghwan Son, Suwon-si (KR); Jaeho Ahn, Suwon-si (KR); Sukkang Sung, Suwon-si (KR)

(73) Assignee: SAMSUNG ELECTRONICS CO., LTD., Suwon-si (KR)

(21) Appl. No.: 19/347,968

(22) Filed: Oct. 2, 2025

(30) Foreign Application Priority Data
Dec. 5, 2024 (KR) 10-2024-0179436

(51) Int. Cl. H10B 43/40; G11C 5/06; H01L 23/00; H01L 25/18; H10B 43/10; H10B 43/27; H10B 43/35; H10D 80/30

(52) U.S. Cl. CPC H10B 43/40; G11C 5/063; H10B 43/10; H10B 43/27; H10B 43/35; H10D 80/30; H10W 90/00; H10W 90/20; H10W 90/24; H10W 90/732; H10W 90/734; H10W 90/752; H10W 90/754; H10W 90/792

(57) ABSTRACT

A semiconductor memory device is provided. The semiconductor memory device includes: a first stack structure on a peripheral circuit structure; and a second stack structure on the first stack structure. The first stack structure includes: a first region including first electrodes and a first vertical channel structure penetrating the first electrodes; and a second region including a buried insulating structure penetrating the first electrodes and a penetration via penetrating the buried insulating structure. The second stack structure includes: a third region on the first region, the third region including second electrodes and a second vertical channel structure penetrating the second electrodes; and a fourth region on the second region. The second region and the fourth region have different structural configurations.

### CROSS-REFERENCE TO RELATED APPLICATION

This application claims priority under 35 U.S.C. § 119 of Korean Patent Application No. 10-2024-0179436, filed on Dec. 5, 2024, the disclosure of which is incorporated by reference herein in its entirety.

### BACKGROUND

The present disclosure relates to a semiconductor memory device and an electronic system including the same.

A semiconductor device that can store a large amount of data is used an electronic system that stores data. Accordingly, research on methods for increasing data storage capacity of the semiconductor device is being carried out. For example, as one of the methods for increasing the data storage capacity of the semiconductor device, the semiconductor device including memory cells three-dimensionally arranged instead of memory cells two-dimensionally arranged is proposed.

### SUMMARY

One or more embodiments provide a device with high integration by utilizing an additional region of an uppermost stack structure.

One or more embodiments also provide a passive device or a contact region provided in an additional region of an uppermost stack structure.

According to an aspect of an embodiment, a semiconductor memory device includes: a first stack structure on a peripheral circuit structure; and a second stack structure on the first stack structure. The first stack structure includes: a first region including first electrodes and a first vertical channel structure penetrating the first electrodes; and a second region including a buried insulating structure penetrating the first electrodes and a penetration via penetrating the buried insulating structure. The second stack structure includes: a third region on the first region, the third region including second electrodes and a second vertical channel structure penetrating the second electrodes; and a fourth region on the second region. The second region and the fourth region have different structural configurations.

According to another aspect of an embodiment, a semiconductor memory device includes: a first stack structure on a peripheral circuit structure; and a second stack structure on the first stack structure. The first stack structure includes: a first region including first electrodes and a first vertical channel structure penetrating the first electrodes; and a second region including a buried insulating structure penetrating the first electrodes and a penetration via penetrating the first electrodes. The second stack structure includes: a third region including second electrodes and a second vertical channel structure penetrating the second electrodes, wherein the third region overlaps the first region; and a fourth region, wherein the fourth region overlaps the second region. The second stack structure further includes, in the fourth region, electrodes disposed at the same level as the second electrodes.

According to another aspect of an embodiment, an electronic system includes: a main board; a semiconductor memory device on the main board; and a controller connected to the semiconductor memory device on the main board. The semiconductor memory device includes: a first stack structure on a peripheral circuit structure; and a second stack structure on the first stack structure. The first stack structure includes: a first region including first electrodes and a first vertical channel structure penetrating the first electrodes; and a second region including a buried insulating structure penetrating the first electrodes and a penetration via penetrating the first electrodes. The second stack structure includes: a third region on the first region, the third region including second electrodes and a second vertical channel structure penetrating the second electrodes; and a fourth region on the second region. The second region and the fourth region have different structural configurations.

According to another aspect of an embodiment, a method of manufacturing a semiconductor memory device, includes: forming a first vertical channel structure extending to a substrate through first electrodes and first insulating layers that are alternately stacked with the first electrodes; forming a penetration via extending to the substrate through a buried insulating layer, wherein the buried insulating layer is provided in a trench penetrating the first electrodes and the first insulating layers; forming an interlayered insulating layer on the substrate, wherein the substrate is provided between the first vertical channel structure and the interlayered insulating layer; and bonding a stack structure to the interlayered insulating layer, the stack structure including memory cells that overlap the trench along a vertical direction.

The method may further include: forming the trench penetrating the first insulating layers and third insulating layers that are alternately stacked with the first insulating layers; and repeatedly forming layers of the buried insulating layer in the trench.

The method may further include: performing a wet etching process to remove third insulating layers that are alternately stacked with the first insulating layers; and forming the first electrodes between the first insulating layers.

The stack structure may include vertical channel structures that overlap the trench along the vertical direction.

### BRIEF DESCRIPTION OF DRAWINGS

The above and other aspects, features and advantages of embodiments will be more apparent from the following description, taken in conjunction with the accompanying drawings, in which:

FIG. 1 is a diagram schematically illustrating an electronic system including a semiconductor memory device according to embodiments;

FIG. 2 is a perspective view schematically illustrating an electronic system including a semiconductor memory device according to embodiments;

FIGS. 3 and 4 are cross-sectional views schematically illustrating semiconductor packages according to embodiments;

FIG. 5 is a plan view for describing a semiconductor memory device according to embodiments;

FIG. 6 is a cross-sectional view of a semiconductor memory device according to embodiments;

FIGS. 7 to 11 are diagrams for describing a method for manufacturing a semiconductor memory device according to embodiments;

FIG. 12 is a cross-sectional view of a semiconductor memory device according to embodiments; and

FIG. 13 is a cross-sectional view of a semiconductor memory device according to embodiments.

### DETAILED DESCRIPTION

Embodiments, including a three-dimensional semiconductor memory device, a method for manufacturing the same, and an electronic system, will now be described more fully with reference to the accompanying drawings. Each embodiment provided in the following description is not excluded from being associated with one or more features of another example or another embodiment also provided herein or not provided herein but consistent with the present disclosure. As used herein, the term “and/or” includes any and all combinations of one or more of the associated listed items. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Unless indicated otherwise, terms “higher” and “lower” indicate vertical alignment in relation to the drawings. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain operation of manufacturing an apparatus or structure is described later than another operation, the operation may be performed later than the other operation unless the other operation is described as being performed after the operation.

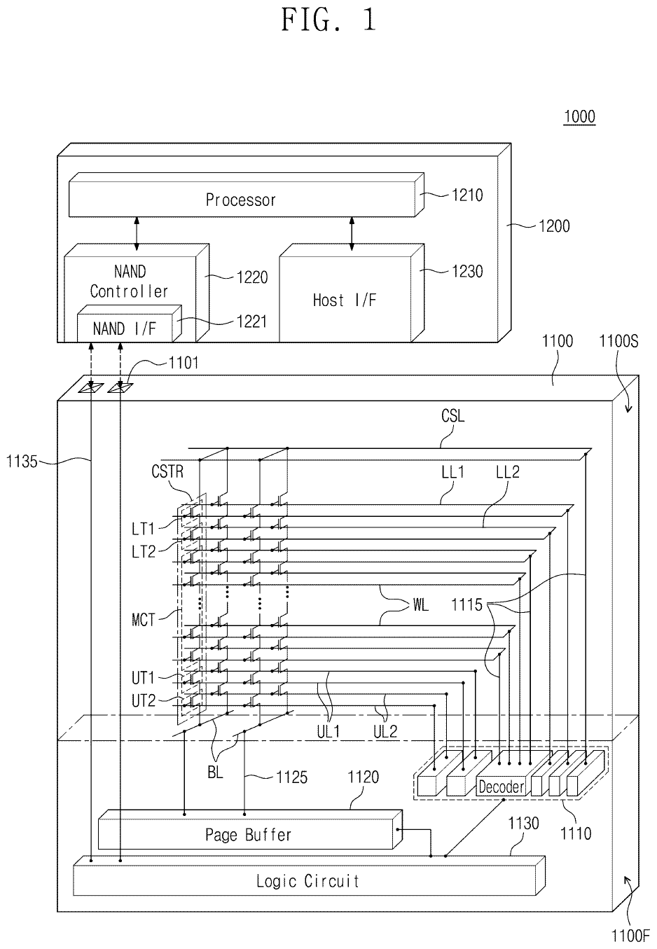

FIG. 1 is a diagram schematically illustrating an electronic system including a three-dimensional semiconductor memory device according to an embodiment.

Referring to FIG. 1, an electronic system 1000 according to an embodiment may include a three-dimensional semiconductor memory device 1100 and a controller 1200 electrically connected to the three-dimensional semiconductor memory device 1100. The electronic system 1000 may be a storage device including one three-dimensional semiconductor memory device 1100 or a plurality of three-dimensional semiconductor memory devices 1100, or an electronic device including the storage device. For example, the electronic system 1000 may be a solid state drive (SSD) device, universal serial bus (USB), a computing system, a medical device, or a communication device including one three-dimensional semiconductor memory device 1100 or a plurality of three-dimensional semiconductor memory devices 1100.

The three-dimensional semiconductor memory device 1100 may be a nonvolatile memory device, and for example, may be a three-dimensional NAND flash memory device to be described later. The three-dimensional semiconductor memory device 1100 may include a first region 1100F and a second region 1100S on the first region 1100F. However, embodiments are not limited thereto and, for example, the first region 1100F may be disposed beside the second region 1100S. The first region 1100F may be a peripheral circuit region including a decoder circuit 1110, a page buffer (e.g., page buffer circuit) 1120, and a logic circuit 1130. The second region 1100S may be a memory cell region including bit lines BL, a common source line CSL, word lines WL, first lines LL1 and LL2, second lines UL1 and UL2, and memory cell strings CSTR between the bit lines BL and the common source line CSL.

In the second region 1100S, each of the memory cell strings CSTR may include first transistors LT1 and LT2 adjacent to the common source line CSL, second transistors UT1 and UT2 adjacent to the bit lines BL, and a plurality of memory cell transistors MCT arranged between the first transistors LT1 and LT2 and the second transistors UT1 and UT2. A number of the first transistors LT1 and LT2 and a number of the second transistors UT1 and UT2 may be variously changed according to embodiments. The memory cell strings CSTR may be located between the common source line CSL and the first region 1100F.

For example, the second transistors UT1 and UT2 may include a string selection transistor, and the first transistors LT1 and LT2 may include a ground selection transistor. The first lines LL1 and LL2 may be gate electrodes of the first transistors LT1 and LT2. The word lines WL may be gate electrodes of the memory cell transistors MCT, and the second lines UL1 and UL2 may be gate electrodes of the second transistors UT1 and UT2.

The common source line CSL, the first lines LL1 and LL2, the word lines WL, and the second lines UL1 and UL2 may be electrically connected to the decoder circuit 1110 through first connection wires 1115 extending from the first region 1100F to the second region 1100S. The bit lines BL may be electrically connected to the page buffer 1120 through second connection wires 1125 extending from the first region 1100F to the second region 1100S.

In the first region 1100F, the decoder circuit 1110 and the page buffer 1120 may execute a control operation for at least one selection memory cell transistor among the plurality of memory cell transistors MCT. The decoder circuit 1110 and the page buffer 1120 may be controlled by the logic circuit 1130. The three-dimensional semiconductor memory device 1100 may communicate with the controller 1200 through an input-output pad 1101 electrically connected to the logic circuit 1130. The input-output pad 1101 may be electrically connected to the logic circuit 1130 through an input-output connection wire 1135 extending from the first region 1100F to the second region 1100S.

The controller 1200 may include a processor 1210, a NAND controller 1220, and a host interface 1230. According to embodiments, the electronic system 1000 may include a plurality of three-dimensional semiconductor memory devices 1100, and in this case, the controller 1200 may control the plurality of three-dimensional semiconductor memory devices 1100.

The processor 1210 may control an overall operation of the electronic system 1000 including the controller 1200. The processor 1210 may operate according to a predetermined firmware and control the NAND controller 1220 to access the three-dimensional semiconductor memory device 1100. The NAND controller 1220 may include a NAND interface 1221 which processes communication with the three-dimensional semiconductor memory device 1100. A control command for controlling the three-dimensional semiconductor memory device 1100, a data to be written to the memory cell transistors MCT of the three-dimensional semiconductor memory device 1100, a data to be read from the memory cell transistors MCT of the three-dimensional semiconductor memory device 1100, etc., may be transferred through the NAND interface 1221. The host interface 1230 may provide a function of communication between the electronic system 1000 and an external host. When a control command is received from the external host through the host interface 1230, the processor 1210 may control the three-dimensional semiconductor memory device 1100 in response to the control command.

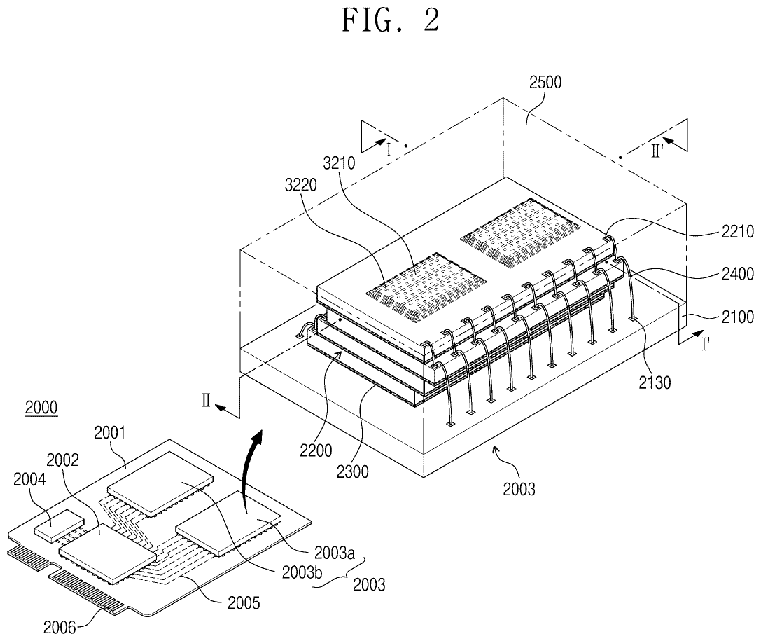

FIG. 2 is a perspective view schematically illustrating the electronic system including the three-dimensional semiconductor memory device according to embodiments.

Referring to FIG. 2, an electronic system 2000 according to an embodiment may include a main board 2001, a controller 2002 mounted on the main board 2001, at least one semiconductor package 2003 and a dynamic random-access memory (DRAM) 2004. The semiconductor package 2003 and the DRAM 2004 may be connected to the controller 2002 by wiring patterns 2005 provided to the main board 2001.

The main board 2001 may include a connector 2006 including a plurality of pins which are coupled to an external host. A number and disposition of the plurality of pins in the connector 2006 may be changed according to communication interface between the electronic system 2000 and the external host. For example, the electronic system 2000 may communicate with the external host according to one among interfaces such as universal serial bus (USB), peripheral component interconnect express (PCI-express), serial advanced technology attachment (SATA), and M-phy for universal flash storage (UFS). For example, the electronic system 2000 may operate by power supplied by the external host through the connector 2006. The electronic system 2000 may further include a power management integrated circuit (PMIC) which distributes the power supplied by the external host to the controller 2002 and the semiconductor package 2003.

The controller 2002 may write to or read data from the semiconductor package 2003, and may improve operation speed of the electronic system 2000.

The DRAM 2004 may be a buffer memory for mitigating a difference in speed between an external host and the semiconductor package 2003 which is a data storage space. The DRAM 2004 included in the electronic system 2000 may also operate as a kind of cache memory, and may provide a space for temporarily storing a data in a control operation for the semiconductor package 2003. In a case in which the DRAM 2004 is included in the electronic system 2000, the controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. The first and second semiconductor packages 2003a and 2003b may each be a semiconductor package including a plurality of semiconductor chips 2200. The first and second semiconductor packages 2003a and 2003b may each include a package substrate 2100, semiconductor chips 2200 on the package substrate 2100, adhesive layers 2300 respectively disposed on lower surfaces of the semiconductor chips 2200, connection structures 2400 electrically connecting the semiconductor chips 2200 and the package substrate 2100, and a molding layer 2500 covering the semiconductor chips 2200 and the connection structures 2400 on the package substrate 2100.

The package substrate 2100 may be a printed circuit board including package upper pads 2130. Each of the semiconductor chips 2200 may include input-output pads 2210. Each of the input-output pads 2210 may correspond to the input/output pad 1101 of FIG. 1. Each of the semiconductor chips 2200 may include gate stack structures 3210 and memory channel structures 3220. Each of the semiconductor chips 2200 may include a semiconductor memory device to be described later.

The connection structures 2400 may be, for example, bonding wires electrically connecting the input-output pads 2210 and the package upper pads 2130. Accordingly, in each of the first and second semiconductor packages 2003a and 2003b, the semiconductor chips 2200 may be electrically connected to each other in a bonding wire manner, and may be electrically connected to the package upper pads 2130 of the package substrate 2100. According to embodiments, in each of the first and second semiconductor packages 2003a and 2003b, the semiconductor chips 2200 may be electrically connected to each other by a through silicon via instead of the connection structures 2400 in a bonding wire manner.

According to some embodiments, the controller 2002 and the semiconductor chips 2200 may be included in one package. According to some embodiments, the controller 2002 and the semiconductor chips 2200 may be mounted on a separate interposer substrate, not on the main board 2001, and may be connected to each other by a wire provided to the interposer substrate.

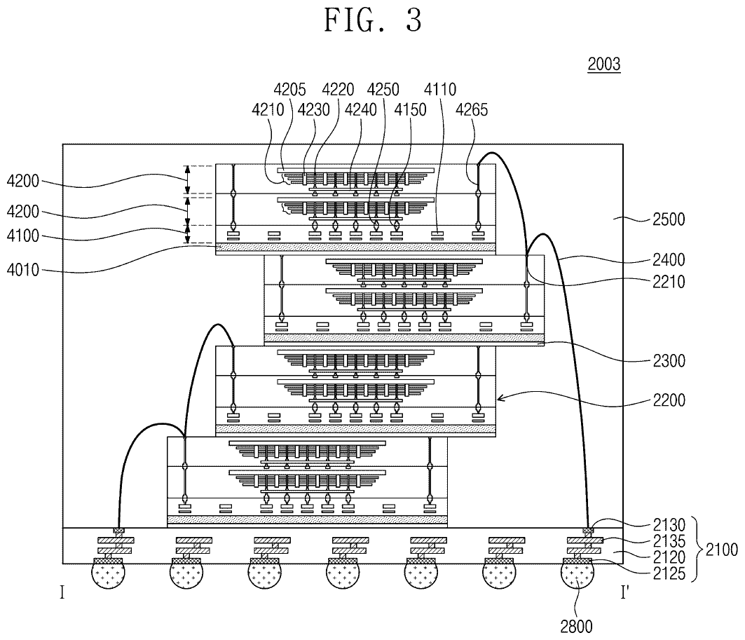

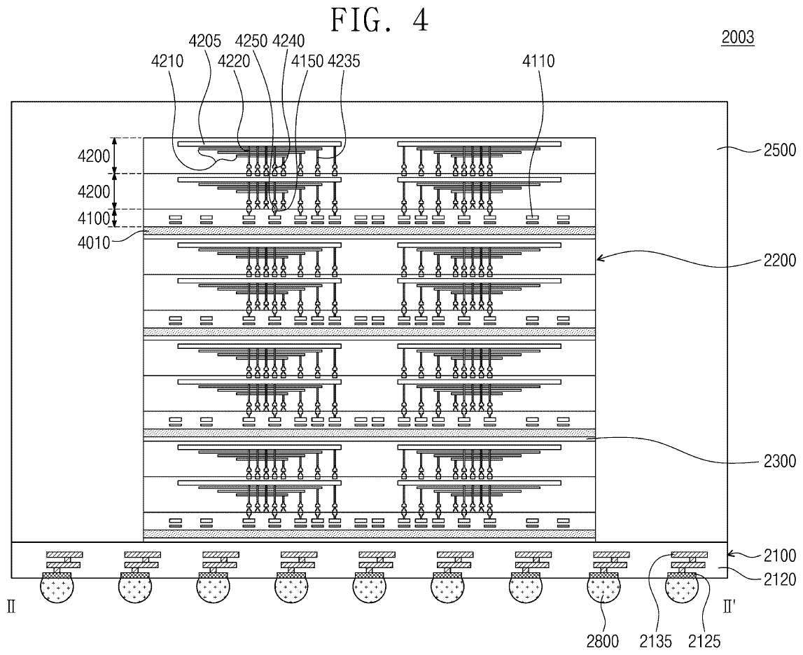

FIGS. 3 and 4 are cross-sectional views for describing the semiconductor package including the three-dimensional semiconductor memory device according to embodiments, and respectively correspond to cross-sections taken along line I-I′ and line II-II′ of FIG. 2.

Referring to FIGS. 3 and 4, the semiconductor package 2003 may include the package substrate 2100, the plurality of semiconductor chips 2200 on the package substrate 2100, and the molding layer 2500 covering the package substrate 2100 and the semiconductor chips 2200.

The package substrate 2100 may include a package substrate body portion 2120, upper pads 2130 disposed on or exposed through an upper surface of the package substrate body portion 2120, lower pads 2125 disposed on or exposed through a lower surface of the package substrate body portion 2120, and internal wires 2135 electrically connecting the upper pads 2130 and the lower pads 2125 inside the package substrate body portion 2120. The upper pads 2130 may be electrically connected to the connection structures 2400. The lower pads 2125 may be connected to the wiring patterns 2005 of the main board 2001 of the electronic system 2000 illustrated in FIG. 2 through conductive connection portions 2800.

Referring to FIGS. 3 and 4, respective sidewalls of the semiconductor chips 2200 may not be aligned with each other, and other respective sidewalls of the semiconductor chips 2200 may be aligned with each other. The semiconductor chips 2200 may be electrically connected to each other by the connection structures 2400 having a bonding wire form. Each of the semiconductor chips 2200 may include the substantially same components.

Each of the semiconductor chips 2200 may include a semiconductor substrate 4010, a first structure 4100 on the semiconductor substrate 4010, and a second structure 4200 on the first structure 4100. The second structure 4200 may be coupled to the first structure 4100 in a wafer bonding manner. Each of the semiconductor chips 2200 may include a plurality of second structures 4200. For example, it is illustrated that each of the semiconductor chips 2200 includes two second structures 4200, but an embodiment is not limited thereto, and at least three second structures 4200 may be provided.

The first structure 4100 may include peripheral circuit wires 4110 and first bonding pads 4150. The second structure 4200 may include a common source line 4205, a gate stack structure 4210 between the common source line 4205 and the first structure 4100, memory channel structures 4220 and separation structures 4230 penetrating the gate stack structure 4210, and second bonding pads 4250 respectively electrically connected to the word lines WL (see FIG. 1) of the gate stack structure 4210 and the memory channel structures 4220. For example, the second bonding pads 4250 may be respectively electrically connected to the word lines WL (see FIG. 1) and the memory channel structures 4220 through bit lines 4240 electrically connected to the memory channel structures 4220 and gate connection wires 4235 electrically connected to the word lines WL (see FIG. 1). The first bonding pads 4150 of the first structure 4100 and the second bonding pads 4250 of the second structure 4200 may be in contact with each other and may be coupled to each other. Coupling portions of the first bonding pads 4150 and the second bonding pads 4250 may include, for example, copper (Cu). As illustrated, when each of the semiconductor chips 2200 includes a plurality of second structures 4200, the second bonding pads 4250 of the plurality of second structures 4200 may be in contact with each other and may be coupled to each other.

Each of the semiconductor chips 2200 may further include the input-output pad 2210 and an input-output connection wire 4265 under the input-output pad 2210. The input-output connection wire 4265 may be electrically connected to some of the second bonding pads 4250 and some of the peripheral circuit wires 4110.

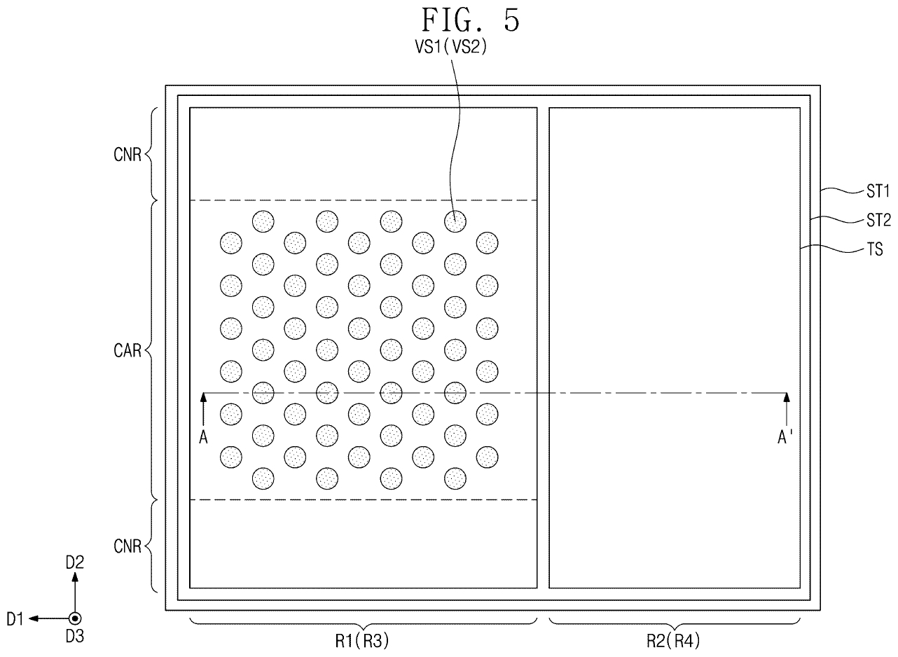

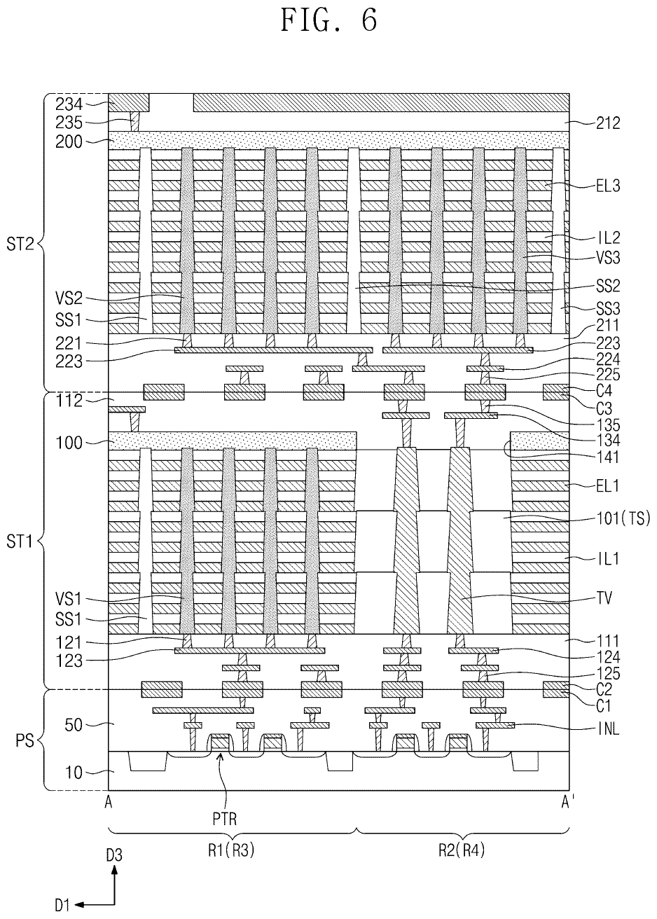

FIG. 5 is a plan view for describing the semiconductor memory device according to embodiments. FIG. 6 is a cross-sectional view taken along line A-A′ of FIG. 5.

Referring to FIGS. 5 and 6, the semiconductor memory device according to embodiments includes a peripheral circuit structure PS, a cell array structure on the peripheral circuit structure PS. The cell array structure may include a first stack structure ST1 and a second stack structure ST2 on the first stack structure ST1. The peripheral circuit structure PS may include a lower substrate 10. The lower substrate 10 may be a silicon substrate, a silicon-germanium substrate, a germanium substrate, or a single crystalline epitaxial layer grown on a single crystalline silicon substrate. The lower substrate 10 may include active regions defined by an element separation layer. As described above, peripheral transistors PTR may constitute a decoder circuit, a page buffer, a logic circuit, and the like.

The peripheral circuit structure PS may include lower wires INL provided on the peripheral transistors PTR, and a first interlayered insulating layer 50 covering the peripheral transistors PTR and the lower wires INL. Peripheral contacts electrically connecting the lower wire INL and the peripheral transistor PTR may be provided therebetween. The first interlayered insulating layer 50 may include multiple insulating layers that are stacked. For example, the first interlayered insulating layer 50 may include a silicon oxide layer, a silicon nitride layer, a silicon oxynitride layer and/or a low-dielectric layer.

The peripheral circuit structure PS may include first connection conductive patterns C1 in an upper portion of the first interlayered insulating layer 50. For example, the first connection conductive patterns C1 may include copper. The first connection conductive patterns C1 may be patterns for providing electrical and physical connections.

The cell array structure may include the first stack structure ST1 and the second stack structure ST2. Hereinafter, the cell array structure is described as including two stack structures, but an embodiment is not limited thereto, and the cell array structure may include two or more stack structures. That is, for example, a third stack structure may be provided between the first stack structure ST1 and the second stack structure ST2.

The first stack structures ST1 and ST2 of FIGS. 6 to 13 may correspond to the second structure 4200 of FIGS. 3 and 4. The peripheral circuit structure PS of FIGS. 6 to 13 may correspond to the first structure 4100 of FIGS. 3 and 4. In more detail, the first stack structure ST1 of FIGS. 6 to 13 may correspond to a topmost one of the second structures 4200 in each semiconductor chips 2200 illustrated in FIGS. 3 and 4. The second stack structure ST2 of FIGS. 6 to 13 may correspond to other one below the topmost one of the second structures 4200 in each semiconductor chips 2200 illustrated in FIGS. 3 and 4.

The first stack structure ST1 in contact with the first interlayered insulating layer 50 of the peripheral circuit structure PS may be provided. The first stack structure ST1 may include a first substrate 100 and a plurality of first electrodes EL1. The first electrodes EL1 may be spaced apart from each other with the first insulating layers IL1 therebetween. The first substrate 100 may be provided on or under the first electrodes EL1. Hereinafter, an example is described in which the first substrate 100 is provided on the first electrodes EL1, but an embodiment is not limited thereto. The first substrate 100 may be a silicon substrate, a silicon-germanium substrate, a germanium substrate or a single crystalline epitaxial layer grown on a single crystalline silicon substrate.

The first stack structure ST1 may include a cell array region CAR and a connection region CNR. The cell array region CAR may be a region in which first vertical channel structures VS1 (described later) are provided. The connection region CNR may be a region in which word line contact plugs for electrical connection of each of the first electrodes EL1 are provided. The word line contact plugs may be the first connection wires 1115 of FIG. 1. As illustrated in FIGS. 2 to 4, the first electrodes EL1 may have a step structure in the connection region CNR. The step structure of the first stack structure ST1 may have a height decreasing in a direction getting farther from the cell array region CAR. An end portion of each of the electrodes EL may be exposed by the step structure, the word line contact plugs may be respectively connected to the end portions of the first electrodes EL1. The connection region CNR may include a pair of regions spaced apart from each other in the second direction D2 with the cell array region CAR therebetween. The connection region CNR may be disposed beside the cell array region CAR in the first direction D1 or in an opposite direction of the first direction D1. The connection region CNR is not limited to the step structure described above, and contact plugs penetrating the first electrodes EL1 may be provided without the step structure.

An uppermost pair of first electrodes EL1 among the first electrodes EL1 of the first stack structure ST1 may be gate electrodes of the first transistors LT1 and LT2 described with reference to FIG. 1, and a lowermost pair of first electrodes EL1 may be gate electrodes of the second transistors UT1 and UT2 described with reference to FIG. 1. The rest of the first electrodes EL1 except for the two pairs of first electrodes EL1 may be the word lines WL.

Each of the first electrodes EL1 may include at least one of a doped semiconductor (e.g., doped silicon), metal (e.g., tungsten, copper, or aluminum), conductive metal nitride (e.g., titanium nitride or tantalum nitride), or transition metal (e.g., titanium or tantalum). The first insulating layers IL1 may include a silicon oxide layer.

The first stack structure ST1 may include a first region R1 and a second region R2. The first region R1 may include the cell array region CAR and the connection region CNR. The second region R2 will be described later. The first vertical channel structures VS1 disposed in the first region R1 may be arranged as illustrated in FIGS. 2 to 5. For example, as illustrated in FIG. 5, four first vertical channel structures VS1 may be arranged along the first direction D1 to form a first column, and five first vertical channel structures VS1 may be arranged along the first direction D1 to form a second column. The first column and the second column may be repeatedly and alternately arranged along the second direction D2. Each of the first vertical channel structures VS1 may have a shape in which a plurality of tapered pillars are connected to each other toward the first substrate 100. That is, the first vertical channel structures VS1 may include step parts in which diameters of the first vertical channel structures VS1 discontinuously change. Alternatively, each of the first vertical channel structures VS1 may have a diameter continuously decreasing toward the first substrate 100.

The first vertical channel structures VS1 may be respectively provided in channel holes penetrating the first stack structure ST1. Each of the first vertical channel structures VS1 may include an information storage layer, a vertical channel pattern and a buried insulating pattern. The vertical channel pattern may be interposed between the information storage layer and the buried insulating pattern. A conductive pad may be provided on a lower portion of each of the first vertical channel structures VS1. The vertical channel pattern may be spaced apart from the first electrodes EL1 with the information storage layer therebetween.

The information storage layer may include a blocking insulating layer, a charge storage layer and a tunneling insulating layer sequentially stacked on a sidewall of the channel hole. The blocking insulating layer may be adjacent to the channel hole, and the tunneling insulating layer may be adjacent to the vertical channel pattern. The charge storage layer may be interposed between the blocking insulating layer and the tunneling insulating layer. The charge storage layer may store and/or change a data by a Fowler-Nordheim tunneling phenomenon derived by a voltage difference between the vertical channel pattern and the first electrodes EL1. For example, the blocking insulating layer and the tunneling insulating layer may include silicon oxide, and the charge storage layer may include silicon nitride or silicon oxynitride.

The vertical channel pattern may include a semiconductor material such as silicon (Si), germanium (Ge), or a mixture thereof. In addition, the vertical channel pattern may be a semiconductor doped with an impurity, or an intrinsic semiconductor not doped with an impurity. For example, the vertical channel pattern may include polysilicon. Alternatively, the vertical channel pattern may include an oxide semiconductor such as IGZO. The vertical channel pattern including a semiconductor material may be used as channels of a transistor that constitutes a NAND cell string.

The conductive pad may include a semiconductor material doped with an impurity and/or a metal material. The vertical channel pattern may be electrically connected to the bit lines 123 to be described later through the conductive pad. The buried insulating pattern may include silicon oxide and/or silicon oxynitride.

Dummy structures may be provided in the connection region CNR. Similar to the first vertical channel structures VS1, the dummy structures may include the charge storage layer, the vertical channel pattern and the buried insulating pattern. In contrast to the first vertical channel structures VS1, the dummy structures may not function as a channel of a memory cell. For example, the dummy structures may not be electrically connected to (i.e., may be electrically insulated or electrically separated from) the bit lines 123 (described later). That is, the dummy structures may not be used in performing operations in the circuit. The dummy structures may serve as pillars (that is, supporters) that physically support the step structure of the first stack structure ST1.

An upper portion of each of the first vertical channel structures VS1 may be connected to a source region. The source region may be a doped region in the first substrate 100, or a source semiconductor layer provided between the first substrate 100 and the first vertical channel structures VS1. For example, the source semiconductor layer may electrically connect a plurality of vertical channel patterns. In this regard, the vertical channel patterns of the first vertical channel structures VS1 may be electrically connected to the source semiconductor layer. A common source voltage may be applied to the source semiconductor layer. For example, the source semiconductor layer may horizontally extend and may penetrate the information storage layer to be in contact with the vertical channel patterns. The source semiconductor layer may include at least one of a semiconductor material (for example, silicon (Si), germanium (Ge), silicon-germanium (SiGe), gallium arsenide (GaAs), indium gallium arsenide (InGaAs), aluminum gallium arsenide (AlGaAs) or a mixture thereof.

A plurality of separation insulating patterns penetrating the first electrodes EL1 may be provided. For example, a first separation insulating pattern SS1 may be provided in trenches penetrating the first electrodes EL1. The first separation insulating pattern SS1 may extend along the second direction D2. On a plan view, the first separation insulating pattern SS1 may have a form of a line or a bar extending in the second direction D2. For example, the first separation insulating pattern SS1 may extend from the cell array region CAR to the connection region CNR, and may horizontally separate a plurality of first electrodes EL1. For example, the first separation insulating pattern SS1 horizontally divide each of the plurality of first electrodes EL1 into two sections. The first separation insulating pattern SS1 may include an insulating material such as silicon oxide. A cross-sectional shape of the first separation insulating pattern SS1 may be, similarly to the first vertical channel structures VS1, a shape in which a plurality of tapered pillars are connected toward the first substrate 100. That is, the first separation insulating pattern SS1 may include step parts in which diameters of the first vertical channel structures VS1 discontinuously change. Alternatively, the first separation insulating pattern SS1 may have a diameter continuously decreasing toward the first substrate 100.

The first stack structure ST1 may include a second interlayered insulating layer 111 in a lower portion thereof, and may include a third interlayered insulating layer 112 in an upper portion thereof. Bit lines 123, bit line contact plugs 121, a first wire 124, and first contact plugs 125 may be provided in the second interlayered insulating layer 111. The bit lines 123 may be electrically connected to the vertical channel patterns of the first vertical channel structures VS1 through the bit line contact plugs 121. Second connection conductive patterns C2 may be provided in a lower surface of the second interlayered insulating layer 111. For example, the second connection conductive patterns C2 may include copper. The second connection conductive patterns C2 may be physically and electrically connected to the first connection conductive patterns C1. Interfaces between the first connection conductive patterns C1 and the second connection conductive patterns C2 may not be present or may not be observed. Similarly, an interface between the second interlayered insulating layer 111 of the first stack structure ST1 and the first interlayered insulating layer 50 of the peripheral circuit structure PS may be observed, but may not be observed in other embodiments.

The first stack structure ST1 may include a buried insulating structure TS and penetration vias TV in the second region R2. The buried insulating structure TS may penetrate the first electrodes EL1. The buried insulating structure TS may include a plurality of buried insulating layers 101. As illustrated in FIG. 5, the buried insulating structure TS may have a shape of a line or a bar extending in the second direction D2. The buried insulating structure TS may be in contact with sidewalls of the first electrodes EL1 and sidewalls of the first insulating layers ILL. A separation insulating pattern having a similar form to the first separation insulating pattern SS1 may be additionally provided between the buried insulating structure TS and the first electrodes EL1. The buried insulating structure TS may include at least one of a silicon oxide layer, a silicon nitride layer or a silicon oxynitride layer.

The penetration vias TV may be electrically connected to the peripheral transistors PTR of the peripheral circuit structure PS through the first wire 124, the first contact plugs 125, the first connection conductive patterns C1 and the second connection conductive patterns C2. Each of the penetration vias TV may have a shape in which a plurality of tapered pillars are connected to each other in the third direction D3. That is, each of the penetration vias TV may include step parts in which a diameter thereof discontinuously changes. The step parts may be adjacent to boundaries of a plurality of buried insulating layers 101.

Alternatively, the diameters of the penetration vias TV may continuously decrease in the third direction D3. The penetration vias TV may have greater widths in the first direction D1 than the first vertical channel structures VS1, but an embodiment is not limited thereto. The penetration vias TV may include at least one of a doped semiconductor (e.g., doped silicon), metal (e.g., tungsten, copper, or aluminum), conductive metal nitride (e.g., titanium nitride or tantalum nitride), or transition metal (e.g., titanium or tantalum).

The first substrate 100 may include a first opening 141 exposing the penetration vias TV. A planar shape of the first opening 141 may be a shape of a line or a bar, but an embodiment is not limited thereto. The first substrate 100 may not at least partially cover upper surfaces of the penetration vias TV and an upper surface of the buried insulating structure TS.

A second wire 134 and second contact plugs 135 may be provided in the third interlayered insulating layer 112. Third connection conductive patterns C3 may be provided on an upper surface of the third interlayered insulating layer 112. For example, the third connection conductive patterns C3 may include copper. Upper portions of the penetration vias TV may be electrically connected to bit lines of the second stack structure ST2 to be described later through the second wire 134, the second contact plugs 135 and the third connection conductive patterns C3.

Hereinafter, the second stack structure ST2 will be described in more detail. As long as there is no separate description and illustration, a material, a shape, a manufacturing method, and the like of layers that constitute the second stack structure ST2 may be substantially the same as layers that constitute the first stack structure ST1.

The second stack structure ST2 may include the cell array region CAR and the connection region CNR, similarly to the first stack structure ST1. The second stack structure ST2 may include a third region R3 and a fourth region R4. As illustrated in FIGS. 2 to 4, the second electrodes EL2 may have a step structure in the connection region CNR. The third region R3 may be provided on the first region R1, and the fourth region R4 may be provided on the second region R2. That is, on a plan view, the third region R3 may overlap the first region R1, and the fourth region R4 may overlap the second region R2.

The third region R3 of the second stack structure ST2 may include the second electrodes EL2 and second vertical channel structures VS2 penetrating the second electrodes EL2. The second electrodes EL2 may be spaced apart from each other with the second insulating layers IL2 therebetween. The second substrate 200 may be provided on an uppermost second electrode EL2.

Each of the second vertical channel structures VS2 may have a shape in which a plurality of tapered pillars are connected to each other toward the second substrate 200. That is, each of the second vertical channel structures VS2 may include step parts discontinuously changing diameters thereof. Alternatively, diameters of the second vertical channel structures VS2 may continuously decrease toward the second substrate 200. Each of the second vertical channel structures VS2 may be provided in channel holes penetrating the second stack structure ST2. Each of the second vertical channel structures VS2 may include an information storage layer, a vertical channel pattern and a buried insulating pattern.

A pair of uppermost second electrode EL2 among the second electrode EL2 of the second stack structure ST2 may be gate electrodes of the first transistors LT1 and LT2 described with reference to FIG. 1, and may be gate electrodes of the second transistors UT1 and UT2 described with reference to FIG. 1. The rest of the second electrode EL2 except for the two pairs of second electrode EL2 may be word lines.

The second substrate 200 may be a silicon substrate, a silicon-germanium substrate, a germanium substrate or a single crystalline epitaxial layer grown on a single crystalline silicon substrate. Each of the second electrode EL2 may include at least one of a doped semiconductor (e.g., doped silicon), metal (e.g., tungsten, copper, or aluminum), conductive metal nitride (e.g., titanium nitride or tantalum nitride), or transition metal (e.g., titanium or tantalum). The second insulating layer IL2 may include a silicon oxide layer.

A plurality of separation insulating patterns penetrating the second electrodes EL2 may be provided. For example, the first separation insulating pattern SS1 may be provided in trenches penetrating the second electrodes EL2. The first separation insulating pattern SS1 may extend along the second direction D2.

The second stack structure ST2 may include a third interlayered insulating layer 211 in a lower portion thereof, and may include a fourth interlayered insulating layer 212 in an upper portion thereof. Bit lines 223, bit line contact plugs 221, a third wire 224, and third contact plugs 225 may be provided in the third interlayered insulating layer 211. The bit lines 223 may be electrically connected to vertical channel patterns of the second vertical channel structures VS2 through the bit line contact plugs 221. Fourth connection conductive patterns C4 may be provided in a lower surface of the third interlayered insulating layer 211. For example, the fourth connection conductive patterns C4 may include copper. The third connection conductive patterns C3 and the fourth connection conductive patterns C4 may be physically and electrically connected to each other. Interfaces between the third connection conductive patterns C3 and the fourth connection conductive patterns C4 may not be present or may not be observed.

The second vertical channel structures VS2 may be electrically connected to the peripheral transistors PTR of the peripheral circuit structure PS through the bit lines 223, the first to fourth connection conductive patterns C1 to C4, and the penetration vias TV. For example, the second vertical channel structures VS2 may be electrically connected to the page buffer 1120 (see FIG. 1) through the bit lines 223 and the penetration vias TV. That is, the penetration vias TV may be paths for connecting the bit lines of the stack structure thereon and the peripheral circuit structure PS.

The penetration vias TV are not provided in the fourth region R4 of the second stack structure ST2, unlike in the second region R2 of the first stack structure ST1. The fourth region R4 may include the first structure, and the first structure may have a different structure from the penetration vias TV. For example, the first structure may not include the penetration vias TV. The second stack structure ST2 is an uppermost stack structure of a plurality of stack structures, and thus an additional stack structure is not provided thereon. Accordingly, the second stack structure ST2 may utilize the fourth region R4 instead of the penetration vias TV and the buried insulating structure TS, unlike the stack structures thereunder. For example, memory cells, a passive device such as a capacitor, or contacts connected to electrodes may be provided in the first structure, similarly to the third region R3. Hereinafter, each embodiment will be described in more detail.

According to embodiments, the fourth region R4 may further include electrodes disposed at the same level as the second electrodes EL2 provided in the third region R3. For example, similarly to the third region R3, the third electrodes EL3 and the third vertical channel structures VS3 penetrating the same may be provided in the fourth region R4 of the second stack structure ST2. The third vertical channel structures VS3 provided in the fourth region R4 are not dummy cells, and may function as a memory element. For example, the third vertical channel structures VS3 of the fourth region R4 may be connected to the penetration vias TV through the bit lines 223 and the bit line contact plugs 221 thereunder. According to some embodiments, the second stack structure ST2 may include memory cells composed of the third electrodes EL3 and the third vertical channel structures VS3 in the fourth region R4 covering the second region R2.

The second stack structure ST2 may include, between the third region R3 and the fourth region R4, a second separation insulating pattern SS2 horizontally separating electrodes of the third region R3 and the fourth region R4. The second stack structure ST2 may include a third separation insulating pattern SS3 defining the fourth region R4 with the second separation insulating pattern SS2. The second separation insulating pattern SS2 and the third separation insulating pattern SS3 may extend along the second direction D2, and may horizontally separate the second electrodes EL2 and the third electrodes EL3. Materials and shapes of the second separation insulating pattern SS2 and the third separation insulating pattern SS3 may be substantially the same as the first separation insulating pattern SS1. The second separation insulating pattern SS2 and the third separation insulating pattern SS3 may include an insulating material such as silicon oxide.

A fourth wire 234 and fourth contact plugs 235 may be provided in the fourth interlayered insulating layer 212. The second substrate 200 may be electrically connected to the fourth wire 234 through the fourth contact plug 235.

The second stack structure ST2 is an uppermost stack structure of the stack structures. Accordingly, the penetration vias TV for electrically connecting a stack structure thereon to the peripheral circuit structure PS (i.e., as used in the second region R2) are unnecessary. When the buried insulating structure TS and the penetration vias TV are provided to the second stack structure ST2, similarly to the first stack structure ST1, the buried insulating structure TS and the penetration vias TV may be a dummy region actually not used for electrical operations. According to embodiments, the second stack structure ST2, which is an uppermost stack structure, may be utilized as memory cells to increase integration of the semiconductor device.

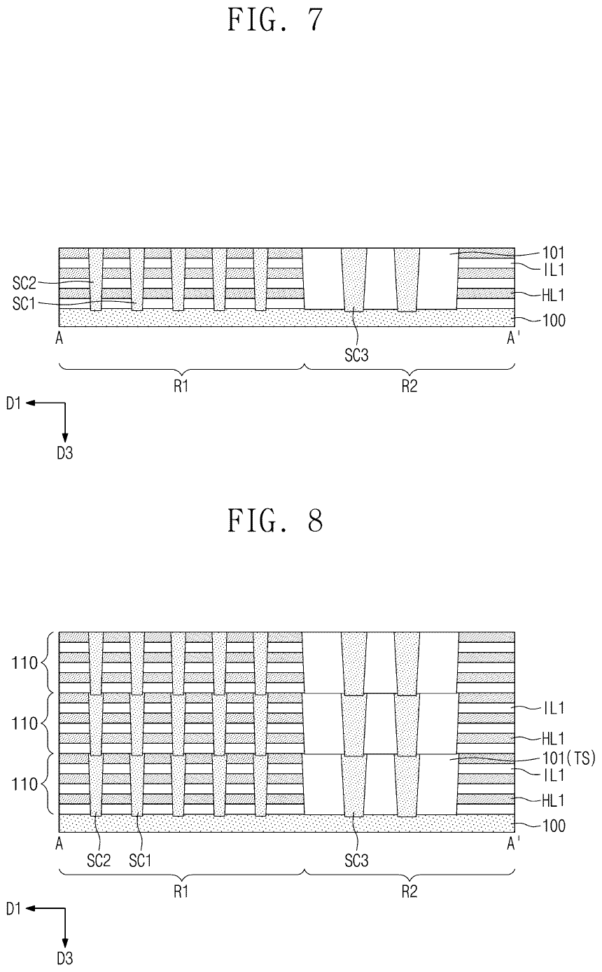

FIGS. 7 to 11 are diagram for describing a method for manufacturing a semiconductor memory device according to embodiments, and are cross-sectional views taken along line A-A′ of FIG. 5.

Referring to FIG. 7, the first insulating layers IL1 and the third insulating layers HL1 may be alternately stacked on the first substrate 100. The first insulating layers IL1 and the third insulating layers HL1 may be deposited using a thermal chemical vapor deposition (CVD) process, a plasma enhanced chemical vapor deposition (PECVD) process, a physical chemical vapor deposition (CVD) process or an atomic layer deposition (ALD) process. The first insulating layers IL1 may include a silicon oxide layer, and the third insulating layers HL1 may include a silicon nitride layer or a silicon oxynitride layer.

The buried insulating layer 101 penetrating the first insulating layers IL1 and the third insulating layers HL1 may be formed. The buried insulating layer 101 may include a material having etching selectivity with the first insulating layers IL1 and the third insulating layers HL1, but an embodiment is not limited thereto. For example, the buried insulating layer 101 may include at least one of silicon oxide, silicon nitride, or silicon oxynitride. The buried insulating layer 101 may be formed in a process of forming a trench penetrating the first insulating layers IL1 and the third insulating layers HL1, and filling the trench with an insulating layer. The buried insulating layer 101 may be formed in the second region R2.

A first sacrificial pattern SC1 and a second sacrificial pattern SC2 penetrating the first insulating layers IL1 and the third insulating layers HL1 may be formed. A third sacrificial pattern SC3 penetrating the buried insulating layer 101 may be formed. The first sacrificial pattern SC1, the second sacrificial pattern SC2 and the third sacrificial pattern SC3 may include a material having etching selectivity with each other, or at least two thereof may include the same material. For example, the first to third sacrificial patterns SC1, SC2 and SC3 may include a polycrystalline silicon layer or a carbon layer. The third sacrificial pattern SC3 may have a greater width than the first and second sacrificial patterns SC1 and SC2.

Referring to FIG. 8, a structure (hereinafter, a mold structure 110) described with reference to FIG. 7 may be formed a plurality of times, and the repeatedly formed structures may be stacked on the first substrate 100. In order to simplify description, three mold structures 110 are illustrated, but an embodiment is not limited thereto. The first sacrificial patterns SC1 may vertically overlap each other, and the first sacrificial patterns SC1 having a tapered shape may be repeatedly stacked. The second and third sacrificial patterns SC2 and SC3 may be stacked, similarly to the first sacrificial patterns SC1. The buried insulating layers 101 may be repeatedly formed to form the buried insulating structure TS.

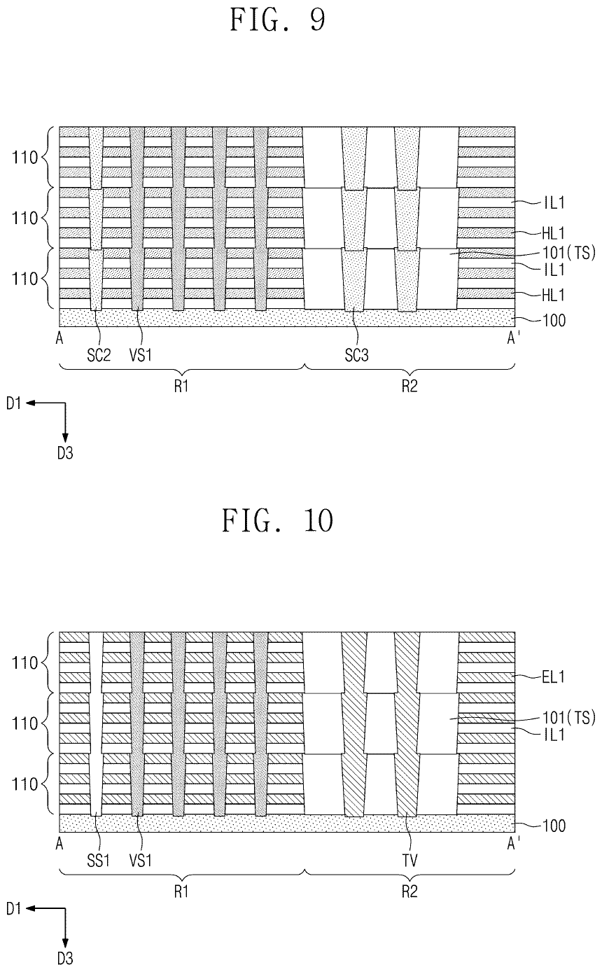

Referring to FIG. 9, the first sacrificial patterns SC1 may be substituted with the first vertical channel structures VS1. The first sacrificial patterns SC1 may be selectively removed. For example, removing the first sacrificial patterns SC1 may include a wet etching process including a phosphoric acid or a hydrofluoric acid. As a result of removing the first sacrificial patterns SC1, channel holes may be formed, and the first vertical channel structures VS1 that fill the channel holes may be formed.

Referring to FIG. 10, the second sacrificial pattern SC2 may be removed to form a trench, and the first electrodes EL1 may be formed in a region in which the third insulating layers HL1 are removed through the trench. Removing the third insulating layers HL1 may include a wet etching process using a phosphoric acid. Thereafter, the trench may be filled with an insulating layer such as a silicon oxide layer to form the first separation insulating pattern SS1.

The third sacrificial pattern SC3 may be removed, and then the penetration vias TV that fill the removed region may be formed. Forming the penetration vias TV may be performed after forming the first separation insulating pattern SS1, but an embodiment is not limited thereto. The penetration vias TV may be formed by forming metal such as tungsten and/or metal nitride such as titanium nitride in a space in which the third sacrificial patterns SC3 are removed, and performing a planarizing process.

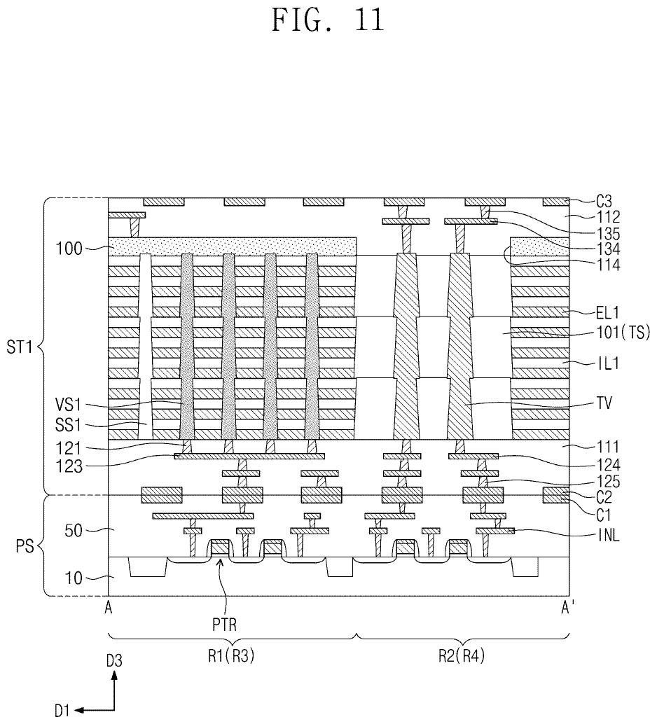

Referring to FIG. 11, the bit lines 123, the bit line contact plugs 121, the first wire 124, and the first contact plugs 125 may be formed in the second interlayered insulating layer 111. The second connection conductive patterns C2 may be formed on a surface of the second interlayered insulating layer 111. Thereafter, a structure including the first substrate 100 may be turned over, and may be bonded to the peripheral circuit structure PS. That is, the first connection conductive patterns C1 and the second connection conductive patterns C2 may be physically bonded to each other, and a heat treatment process may be performed.

Thereafter, the third interlayered insulating layer 112 may be formed on the first substrate 100. The second wire 134 and the second contact plugs 135 may be formed in the third interlayered insulating layer 112. The third connection conductive patterns C3 may be formed on a surface of the third interlayered insulating layer 112. Thereafter, the first stack structure ST1 may be disposed on the peripheral circuit structure PS, and a hot-pressing process may be performed so as to attach the first connection conductive patterns C1 and the second connection conductive patterns C2. The first stack structure ST1 may be formed on the peripheral circuit structure PS in a series of processes like the above.

Referring back to FIG. 6, the second stack structure ST2 may be bonded onto the first stack structure ST1. The second stack structure ST2 may be formed through a substantially similar process to the first stack structure ST1. However, the penetration vias TV and the buried insulating structure TS may not be formed in the fourth region R4 of the second stack structure ST2, unlike in the second region R2 of the first stack structure ST1, and the third electrodes EL3 and the third vertical channel structures VS3 may be provided in the fourth region R4 of the second stack structure ST2 to form memory cells, similarly to the third region R3. The fourth connection conductive pattern C4 of the second stack structure ST2 and the third connection conductive pattern C3 of the first stack structure ST1 may be physically bonded to each other, and then a heat treatment process may be performed.

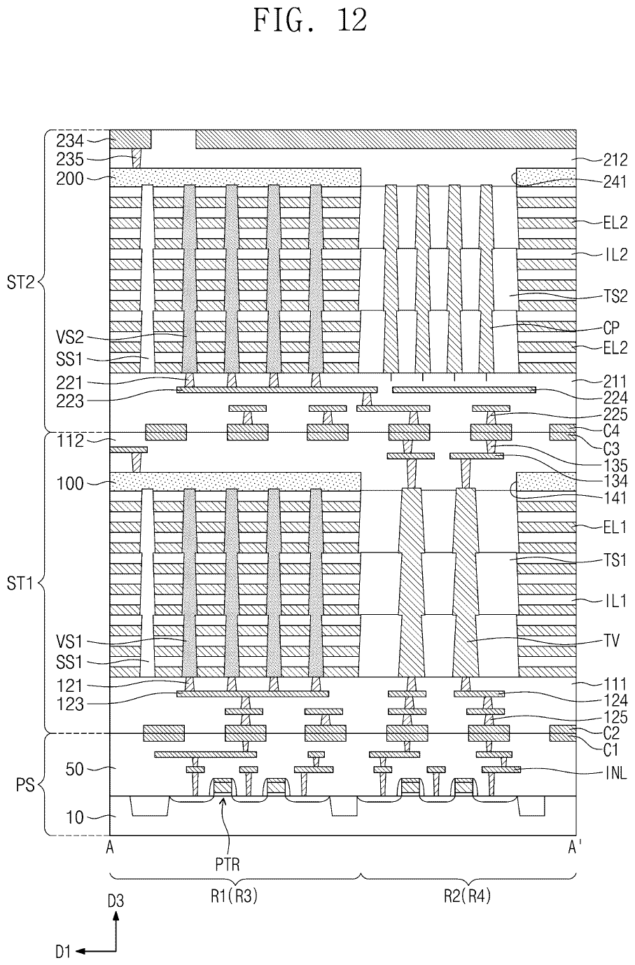

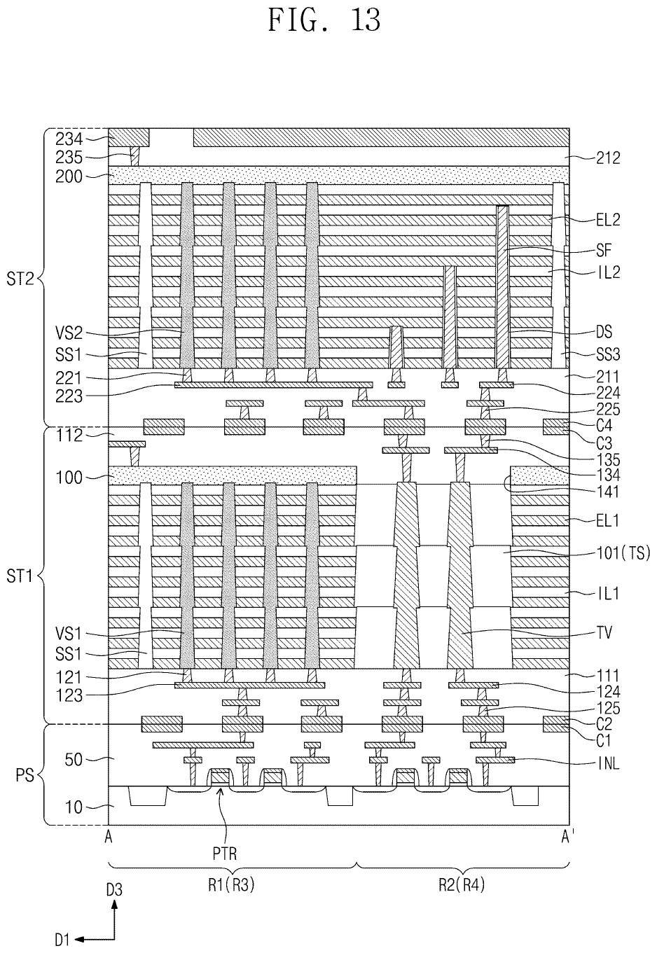

FIG. 12 is a diagram for describing a semiconductor memory device according to embodiments, and is a cross-sectional view taken along line A-A′ of FIG. 5. In order to simplify description, description for duplicate components may be omitted.

Referring to FIG. 12, in the semiconductor memory device according to some embodiments, the fourth region R4 of the second stack structure ST2 may include the first structure, and the first structure may have a different structure from the penetration vias TV. According to some embodiments, the first structure may include a capacitor structure CP. The capacitor structure CP may include a plurality of capacitor electrodes. For example, the capacitor electrodes may have a shape of a plate extending in the second direction D2, but an embodiment is not limited thereto. The capacitor structure CP may be formed in the second buried insulating structure TS2, similarly to the first buried insulating structure TS1 of the first stack structure ST1. Parts of the second buried insulating structure TS2 between the capacitor electrodes having a plate shape may serve as a capacitor dielectric layer. The second buried insulating structure TS2 may include a plurality of buried insulating layers. The second buried insulating structure TS2 may include at least one of a silicon oxide layer, a silicon nitride layer or a silicon oxynitride layer. The capacitor structure CP may include at least one of a doped semiconductor (e.g., doped silicon), metal (e.g., tungsten, copper, or aluminum), conductive metal nitride (e.g., titanium nitride or tantalum nitride), or transition metal (e.g., titanium or tantalum).

The capacitor structure CP may penetrate the second buried insulating structure TS2. Forming the capacitor structure CP may include forming a plurality of trenches penetrating the second buried insulating structure TS2, and then filling the plurality of trenches with a conductive layer. The second substrate 200 may include a second opening 241. The second opening 241 may have a planar shape of a line or a bar, but an embodiment is not limited thereto. The second substrate 200 may not be connected to the capacitor structure CP, or a structure electrically connecting the second substrate 200 and the capacitor structure CP may be provided. The capacitor structure CP may be electrically connected to the third wire 224 through the third contact plugs 225, and/or to the fourth wire 234 through the fourth contact plugs 235. For example, the capacitor structure CP may be connected to the peripheral transistors PTR of the peripheral circuit structure PS through the penetration vias TV, but an embodiment is not limited thereto.

FIG. 13 is a diagram for describing the semiconductor memory device according to embodiments, and is a cross-sectional view taken along line A-A′ of FIG. 5. In order to simplify description, description for duplicate components may be omitted.

Referring to FIG. 13, in the semiconductor memory device according to some embodiments, the fourth region R4 of the second stack structure ST2 may include the first structure, and the first structure may have a different structure from the penetration vias TV. According to some embodiments, the first structure may include word line contacts SF connected to the second electrodes EL2. The word line contacts SF may penetrate at least one of the second electrodes EL2. The word line contacts SF may be electrically separated from the second electrodes EL2 penetrated thereby with insulating spacers DS therebetween. Some of the word line contacts SF are illustrated in FIG. 13, and the rest, of the second electrode EL2, not connected to the word line contacts SF may be connected to the word line contacts SF in another position outside the present cross-section, or to other contacts in a stepwise connection region CNR of the third region R3. The word line contacts SF may include at least one of a doped semiconductor (e.g., doped silicon), metal (e.g., tungsten, copper, or aluminum), conductive metal nitride (e.g., titanium nitride or tantalum nitride), or transition metal (e.g., titanium or tantalum). The insulating spacers DS may include at least one of a silicon oxide layer, a silicon nitride layer or a silicon oxynitride layer. Forming the word line contacts SF may include forming contact holes penetrating the second electrodes EL2, and then sequentially forming an insulating layer and a conductive layer that fill the contact holes. The third separation insulating pattern SS3 may, or may not be provided in the fourth region R4.

According to one or more embodiments, integration of the semiconductor device may be increased by utilizing the fourth region R4 of the second stack structure ST2, which an uppermost stack structure, as one of the memory cells, the capacitor structure and the word line contacts.

According to one or more embodiments, a semiconductor memory device with improved integration may be provided.

While aspects of embodiments have been particularly shown and described, it will be understood that various changes in form and details may be made therein without departing from the spirit and scope of the following claims.

What is claimed is:

1. A semiconductor memory device comprising:
a first stack structure on a peripheral circuit structure; and
a second stack structure on the first stack structure,
wherein the first stack structure comprises:
a first region comprising first electrodes and a first vertical channel structure penetrating the first electrodes; and
a second region comprising a buried insulating structure penetrating the first electrodes and a penetration via penetrating the buried insulating structure,
wherein the second stack structure comprises:
a third region on the first region, the third region comprising second electrodes and a second vertical channel structure penetrating the second electrodes; and
a fourth region on the second region, and
wherein the fourth region has a first structure that is different than a structure of the penetration vias.

2. The semiconductor memory device of claim 1, wherein the second stack structure further comprises bit lines connected to the second vertical channel structure, and
wherein the penetration via connects the bit lines to transistors of the peripheral circuit structure.

3. The semiconductor memory device of claim 2, wherein the second stack structure further comprises bit line contacts connected to lower portions of the second vertical channel structure, and
wherein the bit lines of the second stack structure are provided between the second vertical channel structure and the first stack structure.

4. The semiconductor memory device of claim 1, wherein the first stack structure further comprises a first substrate,
wherein the second stack structure further comprises a second substrate, and
wherein the second electrodes are between the second substrate and the first stack structure.

5. The semiconductor memory device of claim 1, wherein the second stack structure further comprises, in the fourth region, third electrodes and third vertical channel structures penetrating the third electrodes.

6. The semiconductor memory device of claim 5, wherein the second stack structure further comprises a separation insulating pattern horizontally separating electrodes of the third region and the fourth region.

7. The semiconductor memory device of claim 5, wherein the second stack structure further comprises bit lines provided between the first stack structure and the second stack structure, and
wherein the third vertical channel structures are connected to transistors of the peripheral circuit structure through the bit lines and the penetration via.

8. The semiconductor memory device of claim 1, wherein the buried insulating structure of the first stack structure is a first buried insulating structure, and
wherein the fourth region comprises a second buried insulating structure and capacitor electrodes penetrating the second buried insulating structure.

9. The semiconductor memory device of claim 8, wherein the first stack structure further comprises a first substrate,
wherein the second stack structure further comprises a second substrate,
wherein the first substrate defines a first opening through which the penetration via is exposed in the second region, and
wherein the second substrate defines a second opening through which the capacitor electrodes are exposed in the fourth region.

10. The semiconductor memory device of claim 1, further comprising word line contacts connected to the second electrodes.

11. The semiconductor memory device of claim 10, wherein the word line contacts penetrate at least one of the second electrodes.

12. A semiconductor memory device comprising:
a first stack structure on a peripheral circuit structure; and
a second stack structure on the first stack structure,
wherein the first stack structure comprises:
a first region comprising first electrodes and a first vertical channel structure penetrating the first electrodes; and
a second region comprising a buried insulating structure penetrating the first electrodes and a penetration via penetrating the first electrodes,
wherein the second stack structure comprises:
a third region comprising second electrodes and a second vertical channel structure penetrating the second electrodes, wherein the third region overlaps the first region; and
a fourth region, wherein the fourth region overlaps the second region, and
wherein the second stack structure further comprises, in the fourth region, electrodes disposed at the same level as the second electrodes.

13. The semiconductor memory device of claim 12, further comprising:
third electrodes in the fourth region;
third vertical channel structures penetrating the third electrodes; and
a separation insulating pattern horizontally separating the third electrodes from the fourth region.

14. The semiconductor memory device of claim 13, wherein the second stack structure further comprises bit lines provided between the third vertical channel structures and the first stack structure, and
wherein the third vertical channel structures are connected to transistors of the peripheral circuit structure through the bit lines and the penetration via.

15. The semiconductor memory device of claim 12, wherein the second stack structure further comprises, in the fourth region, word line contacts connected to the electrodes.

16. The semiconductor memory device of claim 15, wherein the word line contacts penetrate at least one of the electrodes.

17. The semiconductor memory device of claim 16, wherein each of the word line contacts comprises an insulating spacer between the electrodes.

18. An electronic system comprising:
a main board;
a semiconductor memory device on the main board; and
a controller connected to the semiconductor memory device on the main board,
wherein the semiconductor memory device comprises:
a first stack structure on a peripheral circuit structure; and
a second stack structure on the first stack structure,
wherein the first stack structure comprises:
a first region comprising first electrodes and a first vertical channel structure penetrating the first electrodes; and
a second region comprising a buried insulating structure penetrating the first electrodes and a penetration via penetrating the first electrodes,
wherein the second stack structure comprises:
a third region on the first region, the third region comprising second electrodes and a second vertical channel structure penetrating the second electrodes; and
a fourth region on the second region, and
wherein the fourth region has a first structure that is different than a structure of the penetration vias.

19. The electronic system of claim 18, wherein the second stack structure further comprises bit lines connected to the second vertical channel structure, and
wherein the bit lines are connected to transistors of the peripheral circuit structure through the penetration via.

20. The electronic system of claim 19, wherein the second stack structure further comprises bit line contacts connected to lower portions of the second vertical channel structure, and
wherein the bit lines of the second stack structure are provided between the second vertical channel structure and the first stack structure.
